(19) United States
(12) Patent Application Publication
(10) Pub. No.: US 2026/0173351 A1
(43) Pub. Date: Jun. 18, 2026

(54) SEMICONDUCTOR DEVICE INCLUDING CAPACITOR STRUCTURE

(71) Applicant: Samsung Electronics Co., Ltd., Suwon-si (KR)

(72) Inventors: Inwoo KIM, Suwon-si (KR); Sanghoon AHN, Suwon-Si (KR); Donghyung KIM, Suwon-Si (KR); Yong Kwan KIM, Suwon-si (KR); Hui-Jung KIM, Suwon-si (KR); Gyusoup LEE, Suwon-si (KR); Sangho LEE, Suwon-si (KR); Seongtak CHO, Suwon-si (KR)

(21) Appl. No.: 19/274,866

(22) Filed: Jul. 21, 2025

(30) Foreign Application Priority Data
Dec. 17, 2024 (KR) 10-2024-0188394

(51) Int. Cl. H10B 12/00; H10D 1/68

(52) U.S. Cl. CPC H10B 12/315; H10D 1/716; H10B 12/033

(57) ABSTRACT

A semiconductor device includes a substrate, a plurality of lower electrodes spaced apart from each other on the substrate in a second direction, and a first support disposed on upper surfaces of the plurality of lower electrodes and portions of side surfaces extending from the upper surfaces, in which the first support includes a first support portion overlapping with the plurality of lower electrodes in a first direction perpendicular to the second direction, and a second support portion between the plurality of lower electrodes, each of the plurality of lower electrodes includes a protrusion positioned above a lower surface of the second support portion and a buried portion positioned below the lower surface of the second support portion, and an upper surface of the protrusion is a flat surface and extends in the second direction.

### CROSS-REFERENCE TO RELATED APPLICATION(S)

This application is based on and claims priority to Korean Patent Application No. 10-2024-0188394, filed in the Korean Intellectual Property Office on Dec. 17, 2024, the disclosure of which is hereby incorporated by reference in its entirety.

### BACKGROUND

### 1. Technical Field

The present disclosure relates to a semiconductor device, and more particularly to a semiconductor device including a capacitor.

### 2. Description of the Related Art

A semiconductor device is a core component used in an electronic device to control or amplify an electrical signal, and various types of semiconductor devices can be manufactured. For example, memory devices may be used to store and retrieve data, while non-memory devices may be used to control or amplify electrical signals. The semiconductor device is a key element in the electronic device and can be used in various fields including computers, communication equipment, consumer electronics, etc.

With the development of industry, the performance and function requirements for the electronic devices are increasingly growing. Accordingly, high-performance characteristics in semiconductor devices are required, and the integration density of the semiconductor devices is increasing to meet these requirements. For example, there is a need for a technology that can improve the integration density of Dynamic Random Access Memory (DRAM) devices and form capacitors with excellent electrical characteristics. Therefore, the DRAM device may improve its electrical characteristics by minimizing electrode loss during the capacitor formation process.

### SUMMARY

Example embodiments of the present disclosure provide a semiconductor device with improved electrical characteristics and reliability.

The object to be achieved by the present invention is not limited to the above, and other objects not explicitly described herein may be clearly understood by those skilled in the art from the description of the present disclosure.

According to some aspects of the present disclosure, a semiconductor device is provided, which may include a substrate, a plurality of lower electrodes spaced apart from each other on the substrate in a second direction, and a first support disposed on upper surfaces of the plurality of lower electrodes and on portions of side surfaces extending from the upper surfaces, in which the first support may include a first support portion overlapping with the plurality of lower electrodes in a first direction perpendicular to the second direction, and a second support portion between the plurality of lower electrodes, in which each of the plurality of lower electrodes may include a protrusion positioned above a lower surface of the second support portion and a buried portion positioned below the lower surface of the second support portion, and an upper surface of the protrusion may be a flat surface and extend in the second direction.

According to some aspects of the present disclosure, a semiconductor device may be provided, which may include a substrate, a plurality of lower electrodes spaced apart from each other on the substrate in a second direction, each extending in a first direction perpendicular to the second direction, a support disposed on upper surfaces of the plurality of lower electrodes and on portions of side surfaces extending from the upper surfaces, and a mask pattern disposed between at least one lower electrode of the plurality of lower electrodes and the support in the first direction.

According to some aspects of the present disclosure, a semiconductor device may be provided, which may include a substrate including a plurality of transistors, a capacitor structure disposed on the substrate and connected to the plurality of transistors, in which the capacitor structure may include a plurality of lower electrodes each connected to a corresponding transistor, an upper electrode disposed on the plurality of lower electrodes, and a dielectric film disposed between the plurality of lower electrodes and the upper electrode, and a support disposed on upper surfaces of the plurality of lower electrodes and on portions of side surfaces extending from the upper surfaces, in which the support may include a first support portion overlapping with the plurality of lower electrodes in a first direction, and a second support portion between the plurality of lower electrodes, each of the plurality of lower electrodes may include a protrusion positioned above a lower surface of the second support portion and a buried portion positioned below the lower surface of the second support portion, and an upper surface of the protrusion may be a flat surface and extend in a second direction perpendicular to the first direction.

According to some aspects of the present disclosure, the mask pattern formed on the lower electrodes can minimize a loss of the lower electrodes during the process of forming the support covering the upper region of the lower electrodes, thereby improving the electrical characteristics of the semiconductor device.

### BRIEF DESCRIPTION OF THE DRAWINGS

The above and other objects, features and advantages of the present disclosure will become more apparent to those of ordinary skill in the art by describing in detail exemplary embodiments thereof with reference to the accompanying drawings, in which:

FIG. 1 is a plan view for describing a semiconductor device according to example embodiments;

FIG. 2 is a cross-sectional view taken along line A-A of FIG. 1 according to example embodiments;

FIG. 3 is an enlarged view of a region R of FIG. 2 according to example embodiments;

FIGS. 4 to 8 are diagrams for describing a semiconductor device according to example embodiments;

FIGS. 9 to 11 are diagrams for describing a semiconductor device according to example embodiments;

FIGS. 12 and 13 are diagrams for describing a semiconductor device according to example embodiments;

FIGS. 14 and 15 are diagrams for describing a semiconductor device according to example embodiments; and

FIGS. 16 to 23 are diagrams illustrating a method for manufacturing a semiconductor device according to example embodiments.

### DETAILED DESCRIPTION

Hereinafter, various aspects of the present disclosure will be described with reference to the drawings. Throughout the description, the same reference numerals may refer to the same components.

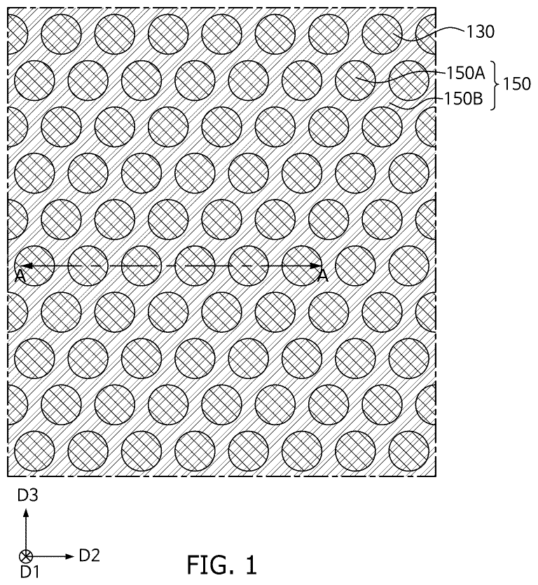

A semiconductor device according to example embodiments will be described with reference to FIGS. 1 to 3.

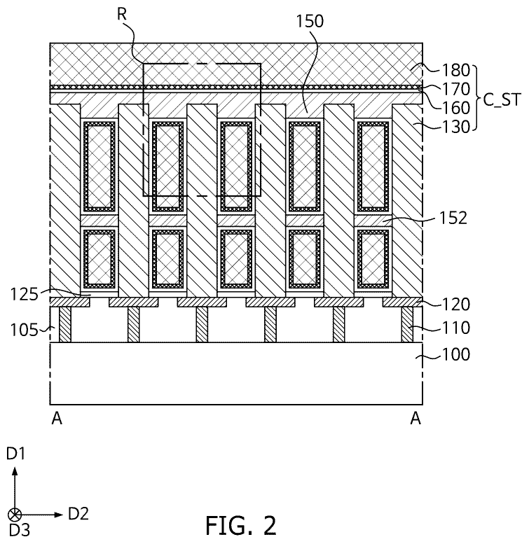

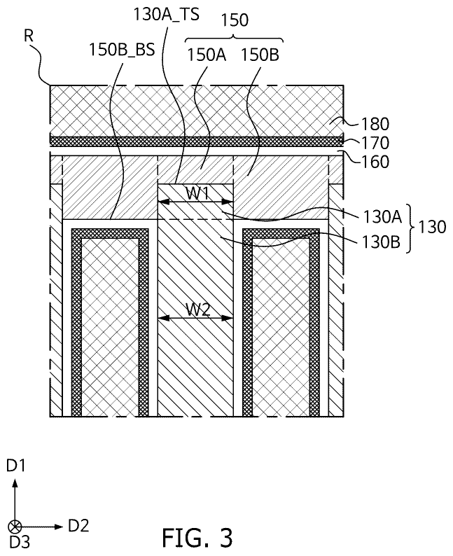

FIG. 1 is a plan view for describing the semiconductor device according to example embodiments. For example, FIG. 1 may correspond to a plan view provided to explain a layout of a lower electrode and a first support of the semiconductor device. FIG. 2 is a cross-sectional view taken along line A-A of FIG. 1 according to example embodiments. FIG. 3 is an enlarged view of a region R of FIG. 2 according to example embodiments. For convenience of description, configurations other than a first support 150 and a lower electrode 130 are omitted from FIG. 1.

Referring to FIGS. 1 and 2, the semiconductor device may include a substrate 100, an interlayer insulating film 105, a contact plug 110, a landing pad 120, an etching stop film 125, the first support 150, a second support 152, and a capacitor structure C_ST.

The substrate 100 may be a bulk silicon or a silicon-on-insulator (SOI). Alternatively, the substrate 100 may include silicon germanium (SiGe), silicon germanium on insulator (SGOI), indium antimony, lead tellurium compound, indium arsenide, indium phosphide, gallium arsenic, or gallium antimony, but is not limited thereto.

The semiconductor device may include a plurality of transistors in the substrate 100. The semiconductor device may be an assembly of the plurality of transistors and a memory device including at least one data storage structure. The semiconductor device may be a dynamic random access memory (DRAM) or a ferroelectric RAM (FeRAM).

The interlayer insulating film 105 may be disposed on the substrate 100. The landing pad 120 may be disposed on top of the interlayer insulating film 105. The contact plug 110 may be disposed in the interlayer insulating film 105. The contact plug 110 may be connected to the landing pad 120. For example, the contact plug 110 may electrically connect a corresponding transistor disposed within the substrate 100 to the landing pad 120.

For example, the interlayer insulating film 105 may include at least one of silicon oxide (SiO), silicon nitride (SiN), silicon oxynitride (SiON), silicon oxycarbonitride (SiOCN), and a combination thereof. For example, the contact plug 110 may include at least one of an impurity-doped semiconductor material, a conductive silicide compound, a conductive metal nitride, and a metal. For example, the landing pad 120 may include at least one of an impurity-doped semiconductor material, a conductive silicide compound, a conductive metal nitride, and a metal. The landing pad 120 may include tungsten (W).

The etching stop film 125 may be disposed on the interlayer insulating film 105. The etching stop film 125 may be disposed on the landing pad 120. The etching stop film 125 may expose at least a portion of the landing pad 120. For example, the etching stop film 125 may include an opening that exposes at least a portion of the landing pad 120.

For example, the etching stop film 125 may include at least one of silicon nitride (SiN), silicon carbon nitride (SiCN), silicon boron nitride (SiBN), silicon carbonate (SiCO), silicon oxynitride (SiON), silicon oxide (SiO), and silicon oxycarbonitride (SiOCN). In the present disclosure, a compound such as silicon carbonate (SiCO) indicates the inclusion of silicon (Si), carbon (C), and oxygen (O), but does not specify a ratio between silicon (Si), carbon (C), and oxygen (O).

The capacitor structure C_ST may be disposed on the substrate 100. The capacitor structure C_ST may store a signal received from the transistor in the substrate 100. The capacitor structure C_ST may be used as a data storage element electrically connected to the transistor. For example, the capacitor structure C_ST may store electric charges under the control of the transistor.

The capacitor structure C_ST may include the lower electrode 130, a dielectric film 160, a conductive film 170, and an upper electrode 180. In an embodiment, the capacitor structure C_ST may include a plurality of lower electrodes 130. For example, each of the plurality of lower electrodes 130 may be connected to a corresponding transistor.

The lower electrode 130 may be disposed on the substrate 100. The lower electrode 130 may be disposed on the landing pad 120. The landing pad 120 may be disposed between the substrate 100 and the lower electrode 130. The lower electrode 130 may be electrically connected to the landing pad 120. A portion of the lower electrode 130 may be disposed in the etching stop film 125. For example, the lower electrode 130 may be formed through the etching stop film 125 and connected to the landing pad 120.

The lower electrode 130 may have a pillar shape. The lower electrode 130 may extend in a first direction D1. The first direction D1 may refer to a direction perpendicular to or substantially perpendicular to an upper surface of the substrate 100.

A plurality of lower electrodes 130 may be disposed in a hexagonal honeycomb structure. For example, each of the plurality of lower electrodes 130 may be disposed at each vertex and center of a hexagon, and the regular hexagonal structure in which each lower electrode 130 is disposed may be repeated. The lower electrodes 130 may be arranged to be spaced apart from each other along a second direction D2, and may be arranged in a zigzag fashion along a third direction D3. However, the inventive aspects are not limited to the above, and from a plan view, the lower electrodes 130 may have various shapes such as a circle, an ellipse, a rectangle, a square, a rhombus. The second direction D2 and the third direction D3 are parallel to the upper surface of the substrate 100 and are perpendicular to each other.

For example, the lower electrode 130 may include at least one of a conductive metal material (e.g., cobalt (Co), titanium (Ti), nickel (Ni), tungsten (W), molybdenum (Mo), etc.), a metal nitride (e.g., titanium nitride (TiN), titanium silicon nitride (TiSiN), titanium aluminum nitride (TiAlN), tantalum aluminum nitride (TaAlN), tungsten nitride (WN), etc.), a precious metal material (e.g., platinum (Pt), ruthenium (Ru), iridium (Ir), etc.), a conductive oxide film (e.g., PtO, RuO2, IrO₂, SRO(SrRuO₃), BSRO((Ba,Sr) RuO₃), CRO(CaRuO₃), LSCo, etc.), and a metal silicide film. However, the inventive aspects are not limited to the above.

The first support 150 may cover an upper portion of the plurality of lower electrodes 130. For example, the first support 150 may be disposed on upper surfaces of the plurality of lower electrodes 130 and on portions of side surfaces of the plurality of lower electrodes 130 extending from the upper surfaces. For example, a side surface of the lower electrode 130 may include a portion that faces the first support 150. As a result, the first support 150 may connect and support the lower electrodes 130 adjacent to each other.

The first support 150 may include a first support portion 150A overlapping with the plurality of lower electrodes 130 in the first direction D1 and a second support portion 150B between the plurality of lower electrodes 130. A thickness of the second support portion 150B may be greater than a thickness of the first support portion 150A. The thickness may refer to a distance from an upper surface to a lower surface of a component in the first direction D1.

The second support 152 may be spaced apart from the first support 150 in the first direction D1. For example, the second support 152 may be disposed below the first support 150. The first support 150 and the second support 152 may overlap with each other in the first direction D1.

The second support 152 may surround middle portions of the plurality of lower electrodes 130. For example, the second support 152 may be disposed on a vertical level that corresponds to the middle portions of the plurality of lower electrodes 130. The second support 152 may be disposed between each of the plurality of lower electrodes 130 to surround a portion of the side surface of each lower electrode 130. The side surface of the lower electrode 130 may include a portion that faces the second support 152. FIG. 2 illustrates that one support (e.g., the second support 152) is disposed in the middle portions of the plurality of lower electrodes 130, but the inventive aspects are not limited thereto. Two or more supports surrounding the plurality of lower electrodes 130 may be disposed below the first support 150.

Each of the first support 150 and the second support 152 may include at least one of, for example, silicon oxynitride (SiON), silicon nitride (SiN), silicon carbon nitride (SiCN), and tantalum oxide (TaO). In some aspects, the first support 150 and the second support 152 may include the same material, but the inventive aspects are not limited thereto. For example, the first support 150 and the second support 152 may include different materials.

The dielectric film 160 may be disposed on an upper surface of the first support 150 and extend along a profile of the upper surface of the first support 150.

In addition, the dielectric film 160 may be disposed on the lower electrode 130, the first support 150, and the second support 152. For example, the dielectric film 160 may be disposed on the side surface of the lower electrode 130, a lower surface of the first support 150, and an upper surface of the second support 152. The side surface of the lower electrode 130 may refer to a side portion of the lower electrode 130 that is positioned between the first support 150 and the second support 152, but is not surrounded by the first support 150 or the second support 152. The dielectric film 160 may extend along the profile of the side surface of the lower electrode 130, the lower surface of the first support 150, and the upper surface of the second support 152.

In addition, the dielectric film 160 may be disposed on the lower electrode 130, the etching stop film 125, and the second support 152. For example, the dielectric film 160 may be disposed on the side surface of the lower electrode 130, a lower surface of the second support 152, and an upper surface of the etching stop film 125. The side surface of the lower electrode 130 may refer to a side portion of the lower electrode 130 that is positioned between the second support 152 and the etching stop film 125, but is not surrounded by the second support 152 or the etching stop film 125. The dielectric film 160 may extend along the profile of the side surface of the lower electrode 130, the lower surface of the second support 152, and the upper surface of the etching stop film 125.

For example, the dielectric film 160 may include a high-k material including a silicon oxide, a silicon nitride, a silicon oxynitride, and a metal. Although it is illustrated that the dielectric film 160 is a single-layered film, this is only for convenience of description, and the inventive aspects are not limited thereto. Unlike the illustration, the dielectric film 160 may include a plurality of films.

The conductive film 170 may be disposed on the dielectric film 160. The conductive film 170 may extend along a profile of the dielectric film 160. The conductive film 170 may cover the dielectric film 160. For example, the dielectric film 160 may be disposed between the first support 150 and the conductive film 170. In addition, the dielectric film 160 may be disposed between the second support 152 and the conductive film 170. In addition, the dielectric film 160 may be disposed between the lower electrode 130 and the conductive film 170. In addition, the dielectric film 160 may be disposed between the etching stop film 125 and the conductive film 170.

For example, the conductive film 170 may include at least one of a doped semiconductor material, a conductive metal nitride (e.g., titanium nitride, tantalum nitride, niobium nitride, tungsten nitride, etc.), a metal (e.g., ruthenium, iridium, titanium, tantalum, etc.), and a conductive metal oxide (e.g., iridium oxide or niobium oxide, etc.), although the inventive aspects are not limited thereto.

The upper electrode 180 may be disposed on the conductive film 170. For example, the upper electrode 180 may fill an empty space between the lower electrodes 130. The upper electrode 180 may fill the space between the plurality of lower electrodes 130 remaining after the dielectric film 160 and the conductive film 170 have been formed.

In addition, the upper electrode 180 may be disposed on the first support 150. For example, the upper electrode 180 may cover the dielectric film 160 and the conductive film 170 provided on the first support 150.

The upper electrode 180 may be electrically connected to the conductive film 170. For example, the upper electrode 180 may include at least one of an element semiconductor material film and a compound semiconductor material film. The upper electrode 180 may include a doped n-type or p-type impurity.

Each of the plurality of lower electrodes 130 may include a protrusion 130A positioned above a lower surface 150B_BS of the second support portion 150B and a buried portion 130B positioned below the lower surface 150B_BS of the second support portion 150B. For example, the protrusion 130A may be positioned at a vertical level higher than the lower surface 150B_BS of the second support portion 150B, and the buried portion 130B may be positioned at a vertical level lower than the lower surface 150B_BS of the second support portion 150B.

The vertical level may refer to a vertical level in the first direction D1. The vertical level may refer to a distance from a reference level to a surface of a specific component in the first direction D1. The reference level may be a vertical level corresponding to the upper or lower surface of any component (e.g., the substrate 100 or the landing pad 120) having a planar surface.

A side surface of the protrusion 130A and a side surface of the buried portion 130B may be aligned in the vertical direction (e.g., the first direction D1). For example, a first width W1 of the protrusion 130A in the second direction D2 may be the same as or substantially the same as a second width W2 of the buried portion 130B in the second direction D2. The first width W1 of the protrusion 130A may refer to an average of the widths measured at all vertical levels of the protrusion 130A in the second direction D2. In addition, the second width W2 of the buried portion 130B may refer to an average of the widths measured at all vertical levels of the buried portion 130B in the second direction D2.

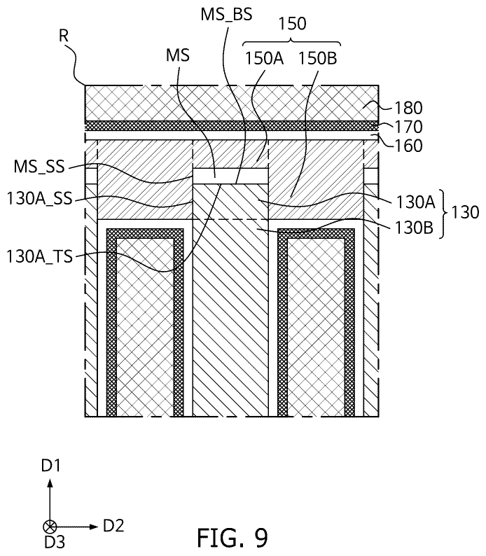

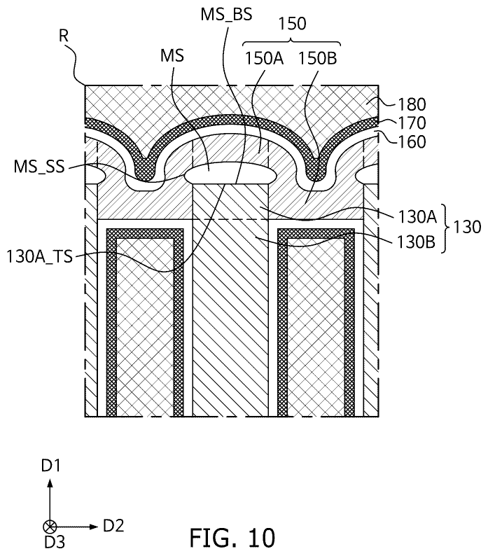

An upper surface 130A_TS of the protrusion 130A may be a flat surface or a non-curved surface. For example, the upper surface 130A_TS of the protrusion 130A may include a flat surface. The flat surface may refer to a non-curved surface that maintains a shape in its deposited state, due to the surface being kept from being etched or substantially etched by the mask pattern formed on the surface. The protrusion 130A of the lower electrode 130 may be a region exposed to the outside by a patterning process. Prior to the patterning process, a mask pattern (e.g., a mask pattern MS of FIGS. 9 to 11) formed by an area-selective deposition (ASD) process may be included on the upper surface of the lower electrode. The mask pattern formed on the upper surface of the lower electrode may be formed such that the upper surface of the lower electrode is relatively less affected by the patterning process so that the upper surface of the lower electrode may have a flat or substantially flat surface.

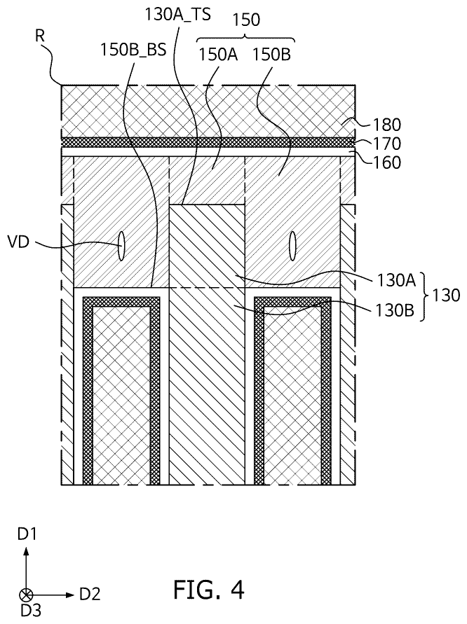

FIGS. 4 to 8 are diagrams for describing a semiconductor device according to example embodiments. For reference, FIGS. 4 to 8 may be diagrams corresponding to the enlarged view of the region R of FIG. 2. For convenience of description, differences from the configurations described above in FIGS. 1 to 3 will be primarily described.

The second support portion 150B may include a void VD therein. Referring to FIG. 4, the void VD, which may have an ellipsoidal shape with a long axis in the first direction D1, may be formed in the second support portion 150B. However, the inventive aspects are not limited to the above, and the void VD may be formed in various shapes. For example, the void VD may have an ellipsoidal shape with a long axis in any direction (e.g., in the second direction D2). The void VD may be formed when a portion of the interior of the second support portion 150B remains unfilled during the process of forming the first support 150.

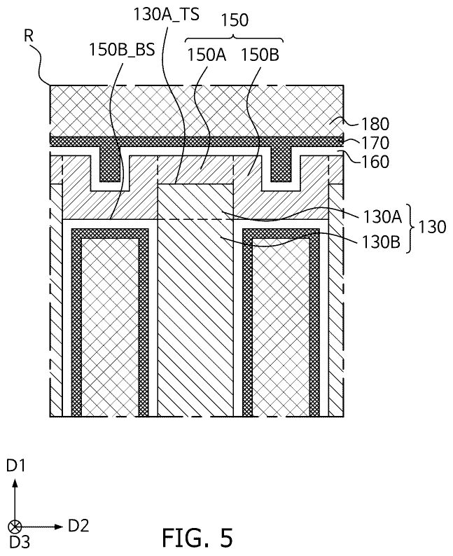

The first support 150 may extend along a profile of an upper region of the plurality of lower electrodes 130. For example, a vertical level of an upper surface of the first support portion 150A and a vertical level of an upper surface of the second support portion 150B may be different from each other. Referring to FIGS. 5 to 8, a vertical level of the uppermost portion of the upper surface of the first support portion 150A may be higher than a vertical level of the lowermost portion of the upper surface of the second support portion 150B. For example, the first support 150 may have a convex shape protruding upward in a region where the first support 150 overlaps with the lower electrode 130 in the vertical direction (e.g., the first direction D1). In addition, the first support 150 may have a concave shape protruding downward in a region between the lower electrodes 130.

In some examples, the protrusion 130A of the lower electrode 130 may have various shapes.

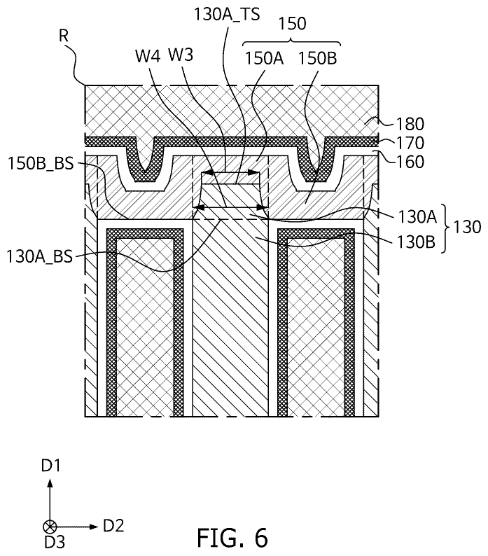

Referring to FIG. 6, the protrusion 130A may gradually decrease in width toward an upper portion thereof. For example, a third width W3 of the upper surface 130A_TS of the protrusion 130A may be narrower than a fourth width W4 of a lower surface 130A_BS of the protrusion 130A. The lower surface 130A_BS of the protrusion 130A may refer to a cross section of the lower electrode 130 at a vertical level corresponding to the lower surface 150B_BS of the second support portion 150B. In addition, each of the third width W3 and the fourth width W4 may refer to a width of the semiconductor device in the second direction D2. The third width W3 may refer to a distance between both side surfaces that face each other in the second direction D2 on the upper surface 130A_TS of the protrusion 130A, and the fourth width W4 may refer to a distance between both side surfaces of the lower electrode 130 that face each other in the second direction D2 at the same vertical level as the lower surface 150B_BS of the second support portion 150B.

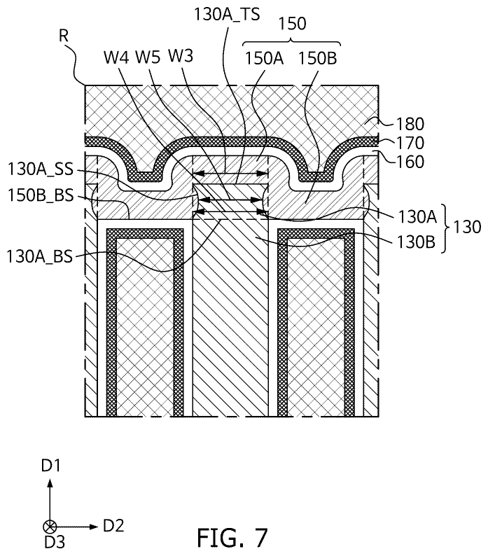

Referring to FIG. 7, a side surface 130A_SS of the protrusion 130A may have a concave shape. More specifically, the protrusion 130A may have a structure in which the side surface 130A_SS of the protrusion 130A is curved inward into the protrusion 130A, causing the width of the protrusion 130A to gradually decrease and then increase in an upward direction. For example, a fifth width W5 of the protrusion 130A at any vertical level between the upper surface 130A_TS and the lower surface 130A_BS of the protrusion 130A may be narrower than the third width W3 of the upper surface 130A_TS of the protrusion 130A and the fourth width W4 of the lower surface 130A_BS of the protrusion 130A.

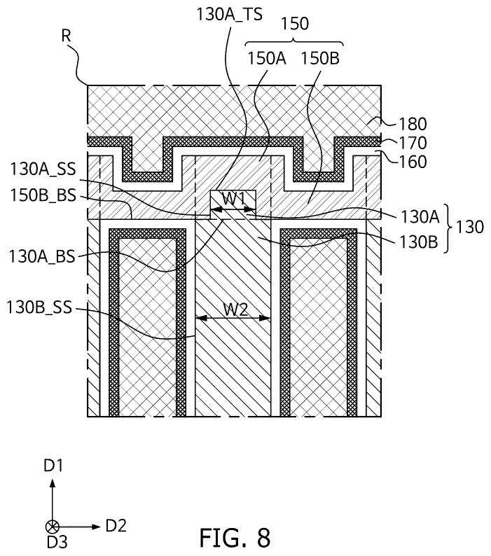

Referring to FIG. 8, the side surface 130A_SS of the protrusion 130A and a side surface 130B_SS of the buried portion 130B may be misaligned in the first direction D1. For example, the side surface 130A_SS of the protrusion 130A may not be on the same plane as the side surface 130B_SS of the buried portion 130B and may be arranged to be spaced apart from each other by a predetermined distance in the second direction D2. The first width W1 of the protrusion 130A may be narrower than the second width W2 of the buried portion 130B.

FIGS. 9 to 11 are diagrams for describing a semiconductor device according to example embodiments. For reference, FIGS. 9 to 11 may be diagrams corresponding to the enlarged view of the region R of FIG. 2. The semiconductor device of FIGS. 9 to 11 may be the same as the semiconductor device described with reference to FIGS. 1 to 8, except for the mask pattern MS. For convenience of description, configurations different from the configuration described above in FIGS. 1 to 8 will be primarily described.

The semiconductor device may further include the mask pattern MS disposed between at least one of the plurality of lower electrodes 130 and the first support 150. For example, the mask pattern MS may be disposed between a lower surface of the first support portion 150A of the first support 150 and the upper surface 130A_TS of the protrusion 130A.

The mask pattern MS may include a nitride film, an oxide film, a polysilicon film, a photoresist film, or a combination thereof. The mask pattern MS may include at least one of a spin on hardmask (SOH) and an amorphous carbon layer (ACL). The mask pattern MS may include a material that has a different etch selectivity than the oxide layer.

A width of the lower surface MS_BS of the mask pattern MS and a width of the upper surface 130A_TS of the protrusion 130A may correspond to each other. For example, the width of the lower surface MS_BS of the mask pattern MS may be the same as or substantially the same as the width of the upper surface 130A_TS of the protrusion 130A.

In some embodiments, the mask pattern MS may have various shapes.

Referring to FIG. 9, a side surface MS_SS of the mask pattern MS may be vertically aligned with the side surface of at least one lower electrode 130. More specifically, the side surface MS_SS of the mask pattern MS may be aligned with the side surface 130A_SS of the protrusion 130A in the vertical direction (e.g., the first direction D1).

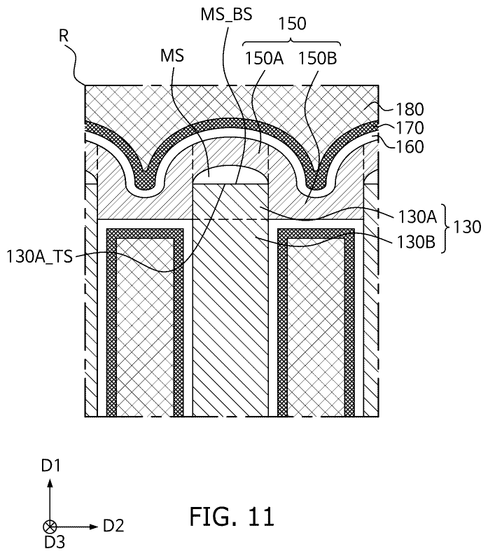

The mask pattern MS may have a curved shape. The side surface MS_SS of the mask pattern MS may have a convex shape. More specifically, the mask pattern MS may have a structure in which the side surface MS_SS of the mask pattern MS is curved outward the mask pattern MS, causing the width of the mask pattern MS to gradually increase and then decrease in an upward direction. An upper surface of the mask pattern MS may have a convex shape. Referring to FIG. 11, the mask pattern MS may gradually decrease in width in the second direction D2 toward an upper portion thereof. For example, the mask pattern MS may be a semi-ellipsoid, but the inventive aspects are not limited thereto.

Aspects of the semiconductor device including the mask pattern MS described with reference to FIGS. 9 to 11 may be combined with aspects of the shape of the protrusion 130A of the lower electrode 130 described with reference to FIGS. 3 to 8. For example, the mask pattern MS described with reference to FIGS. 9 to 11 may be disposed above the lower electrode 130 described with reference to each of FIGS. 3 to 8.

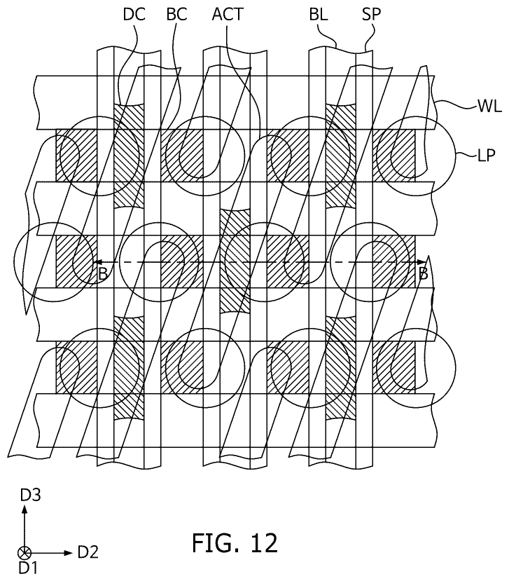

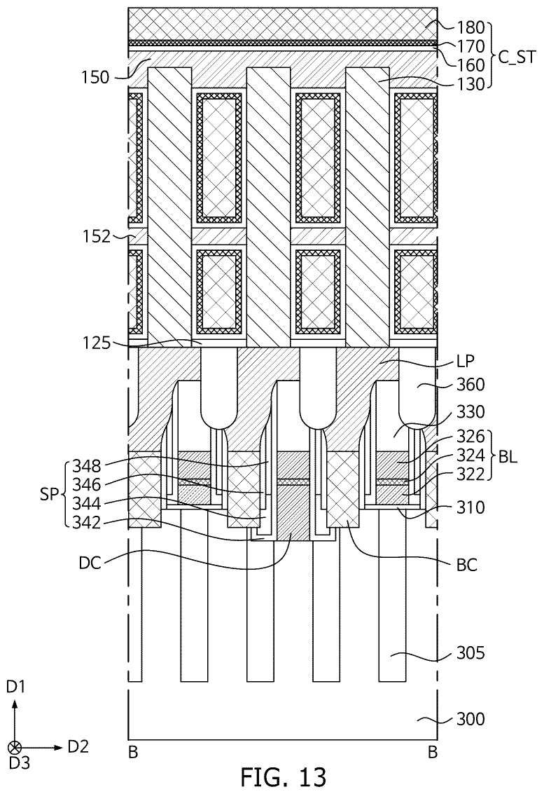

FIGS. 12 and 13 are diagrams for describing a semiconductor device according to example embodiments. For reference, FIG. 12 is a schematic layout view illustrating a semiconductor device according to example embodiments. FIG. 13 is a cross-sectional view taken along the line B-B of FIG. 12 according to example embodiments.

Referring to FIGS. 12 and 13, the semiconductor device may include a plurality of active regions ACT. The active region ACT may be defined by a device isolation film 305 formed in a substrate 300. The substrate 300 may correspond to the substrate 100 of FIG. 2 where the substrate 100 includes both the base substrate 300 and transistor structures formed thereon. The active region ACT may have a bar shape. The plurality of active regions ACT may be spaced apart from each other. The device isolation film 305 may have a shallow trench isolation (STI) structure having excellent device isolation characteristics.

For example, each of device isolation films 305 may include at least one of a silicon oxide film, a silicon nitride film, and a silicon oxynitride film, but is not limited thereto. Although it is illustrated that each of the device isolation films 305 is formed of one insulating film, it is only for convenience of description, and the inventive aspects are not limited thereto.

A word line WL may cross the active region ACT. The word line WL may extend in the second direction D2. A plurality of word lines WL may be disposed to be spaced apart from each other in the third direction D3. The plurality of word lines WL may be disposed at equal intervals. A width of the word line WL, or the interval between the word lines WL may be determined according to a design rule.

In some examples, the word line WL may be disposed on a gate trench formed in the substrate 300 and the device isolation film 305. The word line WL may include a gate insulating film, a gate electrode, and a gate capping pattern.

The gate electrode may include at least one of a metal, a metal alloy, a conductive metal nitride, a conductive metal carbon nitride, a conductive metal carbide, a metal silicide, a doped semiconductor material, a conductive metal oxynitride, and a conductive metal oxide.

A plurality of bit lines BL extending in the third direction D3 perpendicular to the word lines WL may be disposed on the word lines WL. The plurality of bit lines BL may extend parallel to each other. The bit lines BL may be disposed at equal intervals. A width of the bit line BL, or the interval between the bit lines BL may be determined according to a design rule.

The bit line BL may include first to third cell conductive films 322, 324, and 326. The first to third cell conductive films 322, 324, and 326 may be sequentially stacked on the substrate 300 and the device isolation film 305. FIG. 13 illustrates that the bit line BL is a three-layered film, but the inventive aspects are not limited thereto.

Each of the first to third cell conductive films 322, 324, and 326 may include at least one of an impurity-doped semiconductor material, a conductive silicide compound, a conductive metal nitride metal, and a metal alloy.

A bit line capping film 330 may be disposed on the bit line BL. The bit line capping film 330 may extend along an upper surface of the third cell conductive film 326. For example, the bit line capping film 330 may include at least one of a silicon nitride film, a silicon oxynitride, a silicon carbon nitride, and a silicon oxycarbonitride. The bit line capping film 330 is illustrated as a single film, but the inventive aspects are not limited thereto.

A direct contact DC may be formed between the bit line BL and the substrate 300. The direct contact DC may electrically connect the bit line BL to the substrate 300. The bit line BL may be formed on the direct contact DC. For example, the direct contact DC may be formed at a point where the bit line BL intersects with a middle portion of the active region ACT having an elongated island-like shape.

For example, the direct contact DC may include at least one of an impurity-doped semiconductor material, a conductive silicide compound, a conductive metal nitride, and a metal.

The bit line BL may include the second cell conductive film 324 and the third cell conductive film 326 in a region overlapping with an upper surface of the direct contact DC. The bit line BL may include the first to third cell conductive films 322, 324, and 326 in a region not overlapping with the upper surface of the direct contact DC.

A cell insulating film 310 may be formed on the substrate 300 and the device isolation film 305. Specifically, the cell insulating film 310 may be formed on the device isolation film 305 and the substrate 300 where the direct contact DC is not formed. The cell insulating film 310 may be formed between the substrate 300 and the bit line BL, and between the device isolation film 305 and the bit line BL.

Cell line spacers SP may be disposed on sidewalls of the bit line BL and the bit line capping film 330. The cell line spacer SP may be formed on the substrate 300 and the device isolation film 305 at a portion of the bit line BL where the direct contact DC is formed. The cell line spacers SP may be disposed on the sidewalls of the bit line BL, the bit line capping film 330, and the direct contact DC.

However, in the remaining portion of the bit line BL where the direct contact DC is not formed, the cell line spacers SP may be disposed on the cell insulating film 310. The cell line spacers SP may be disposed on the sidewalls of the bit line BL and the bit line capping film 330.

The cell line spacer SP may be a single-layered films, but as illustrated, the cell line spacer SP may be a multi-layered film that includes first to fourth cell line spacers 342, 344, 346, and 348. For example, the first to fourth cell line spacers 342, 344, 346, and 348 may include one of a silicon oxide film, a silicon nitride film, a silicon oxynitride film (SiON), a silicon oxycarbon nitride film (SiOCN), air, and a combination thereof, but are not limited thereto.

The buried contact BC may be disposed between the bit lines BL adjacent to each other in the second direction D2. The buried contact BC may be connected to the active region ACT. The buried contact BC may connect the active region ACT to the capacitor structure C_ST. This structure of arrangement may cause a contact area between the buried contact BC and the active region ACT to be small. Accordingly, the landing pad LP may be disposed to expand the contact area with the active region ACT and also to expand the contact area with the capacitor structure C_ST.

For example, the buried contact BC may include at least one of an impurity-doped semiconductor material, a conductive silicide compound, a conductive metal nitride, and a metal.

The landing pad LP may be formed on the buried contact BC. The landing pad LP may be electrically connected to the buried contact BC. The landing pad LP may be disposed between the active region ACT and the buried contact BC. The landing pad LP may be disposed between the buried contact BC and the lower electrode 130. By expanding the contact area through the landing pad LP, contact resistance between the active region ACT and the lower electrode 130 may be reduced.

For example, the landing pad LP may include at least one of an impurity-doped semiconductor material, a conductive silicide compound, a conductive metal nitride, a conductive metal carbide, a metal, and a metal alloy.

A pad isolation insulating film 360 may be disposed between the landing pads LP. The pad isolation insulating film 360 may electrically separate a plurality of landing pads LP from each other. For example, the pad isolation insulating film 360 may include at least one of a silicon oxide film, a silicon nitride film, a silicon oxynitride film, a silicon oxycarbon nitride film, and a silicon carbon nitride film.

The etching stop film 125 may be disposed on an upper surface of the landing pad LP and an upper surface of the pad isolation insulating film 360. For example, the etching stop film 125 may include at least one of silicon nitride (SiN), silicon carbon nitride (SiCN), silicon oxycarbonitride (SiOCN), silicon oxynitride (SiOC), and silicon boron nitride (SiBN).

The capacitor structure C_ST may be disposed on the landing pad LP. The capacitor structure C_ST may be connected to the landing pad LP. For example, the capacitor structure C_ST may be electrically connected to the buried contact BC.

The capacitor structure C_ST may include the lower electrode 130, the dielectric film 160, the conductive film 170, and the upper electrode 180. The first support 150 may be disposed on the upper surface of the lower electrode 130 and on a portion of the side surface extending from the upper surface of the lower electrode 130. The second support 152 may surround the middle portion of the lower electrode 130. Descriptions of the capacitor structure C_ST, the first support 150, and the second support 152 may be the same as those described in FIGS. 1 to 11.

Additionally, the mask pattern MS may be disposed between the lower electrode 130 and the first support 150. The description of the mask pattern MS may be the same as that described above with reference to FIGS. 9 to 11.

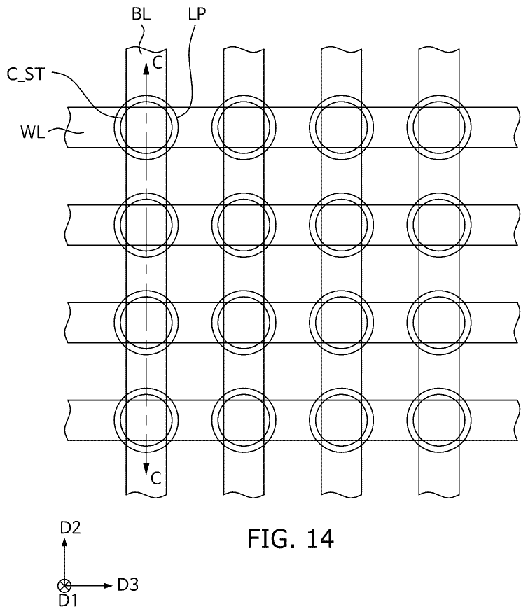

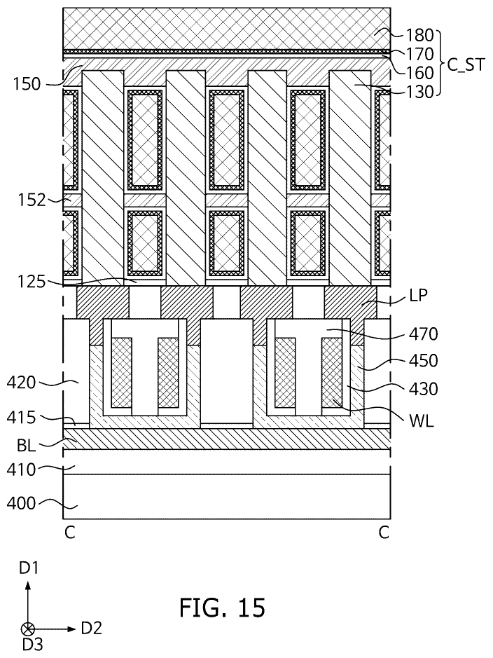

FIGS. 14 and 15 are diagrams for describing a semiconductor device according to example embodiments. For reference, FIG. 15 is a cross-sectional view taken along line C-C of FIG. 14 according to example embodiments.

Referring to FIGS. 14 and 15, the semiconductor device may include a substrate 400, a lower insulating film 410, a bit line BL, a word line WL, a gate insulating film 430, a channel layer 450, a landing pad LP, and a capacitor structure C_ST. The semiconductor device according to some aspects may be a memory device including a vertical channel transistor VCT. The vertical channel transistor may refer to a structure in which a channel length of the channel layer 450 extends from the substrate 400 in the first direction D1 which is the vertical direction.

The lower insulating film 410 may be disposed on the substrate 400. A plurality of bit lines BL may be disposed on the lower insulating film 410. The plurality of bit lines BL may extend in the second direction D2. The plurality of bit lines BL may be disposed to be spaced apart from each other in the third direction D3.

The plurality of bit lines BL may include at least one of doped polysilicon, metal (e.g., Al, Cu, Ti, Ta, Ru, W, Mo, Pt, Ni, and Co), conductive metal nitride (e.g., TiN, TaN, WN, NON, TiAlN, TiSiN, TaSiN, and RuTiN), conductive metal silicide and conductive metal oxide (e.g., PtO, RuO₂, IrO₂, SrRuO₃ (SRO), (Ba,Sr) RuO₃ (BSRO), CaRuO₃ (CRO), and LSCo), but the inventive aspects are not limited thereto.

The plurality of bit lines BL may include a single layer or multiple layers of the materials mentioned above. In some aspects, the plurality of bit lines BL may include graphene, carbon nanotube, or a combination thereof.

A mold etching stop film 415 may be disposed on the bit line BL. A mold pattern 420 may be disposed on the mold etching stop film 415. The mold etching stop film 415 and the mold pattern 420 may extend in the third direction D3. A plurality of mold patterns 420 may be disposed to be spaced apart from each other in the second direction D2.

The channel layer 450 may be disposed on the bit line BL. The channel layer 450 may be disposed between the mold patterns 420. The channel layer 450 may include a horizontal portion in contact with the bit line BL and a vertical portion extending from the horizontal portion in the first direction D1. The vertical portion may include a first vertical portion disposed at one end of the horizontal portion and a second vertical portion disposed at the other end of the horizontal portion. The first vertical portion and the second vertical portion may be spaced apart from each other in the second direction D2. In some examples, unlike the illustration, the horizontal portion of the channel layer may be separated.

The channel layer 450 may include an oxide semiconductor. For example, the oxide semiconductor may include InGaZnO, InGaSiO, InSnZnO, InZnO, ZnO, ZnSnO, ZnON, ZrZnSnO, SnO, HfInZnO, GaZnSnO, AlZnSnO, YbGaZnO, InGaO, or a combination thereof. The channel layer 450 may include a single layer or multiple layers of an oxide semiconductor. In addition, the channel layer 450 may be polycrystalline or amorphous, for example, but is not limited thereto. In some examples, the channel layer 450 may include graphene, carbon nanotube, or a combination thereof.

The gate insulating film 430 may be disposed on the channel layer 450. The gate insulating film 430 may be disposed between the channel layer 450 and the word line WL. The channel layer 450 and the word line WL may be spaced apart from each other by the gate insulating film 430.

The gate insulating film 430 may include a silicon oxide film, a silicon oxynitride film, a high-k insulating film having a dielectric constant higher than that of the silicon oxide film, or a combination thereof.

The word line WL may be disposed on the gate insulating film 430. The word line WL may extend in the third direction D3. The word line WL may extend in the first direction D1 along the vertical portion of the channel layer 450.

In some examples, an upper surface of the word line WL may be disposed higher than an upper surface of the channel layer 450. For example, a distance to the upper surface of the word line WL from an upper surface of the bit line BL may be greater than a distance to an upper surface of the vertical portion of the channel layer 450 from the upper surface of the bit line BL. However, the inventive aspects are not limited to the above. For example, the upper surface of the word line WL may be disposed on the same plane as, or lower than the upper surface of the channel layer 450.

The word line WL may include a conductive material. For example, the word line WL may include at least one of doped polysilicon, conductive metal nitride, conductive metal silicon nitride, metal carbon nitride, conductive metal silicide, conductive metal oxide, a two-dimensional material, a metal, and a metal alloy.

A gate isolation pattern 470 may be disposed between the word lines WL. The word lines WL may be spaced apart from each other by the gate isolation pattern 470. For example, the word line WL disposed on the first vertical portion of the channel layer 450 and the word line WL disposed on the second vertical portion of the channel layer 450 may be spaced apart from each other in the second direction D2 by the gate isolation pattern 470. The gate isolation pattern 470 may include an insulating material.

The landing pad LP may be disposed on the mold pattern 420 and the gate isolation pattern 470. The landing pad LP may include a protrusion that extends toward the channel layer 450. The protrusion of the landing pad LP may be in contact with the vertical portion of the channel layer 450. The landing pad LP may be electrically connected to the channel layer 450.

The landing pad LP may include a conductive material. The landing pad LP may include at least one of doped polysilicon, conductive metal nitride, conductive metal silicon nitride, metal carbon nitride, conductive metal silicide, conductive metal oxide, a two-dimensional material, a metal, and a metal alloy.

The etching stop film 125 may be disposed on an upper surface of the landing pad LP and on an upper surface of a contact interlayer insulating film disposed between the landing pads LP. For example, the etching stop film 125 may include at least one of silicon nitride (SiN), silicon carbon nitride (SiCN), silicon oxycarbonitride (SiOCN), silicon oxynitride (SiON), and silicon boron nitride (SiBN).

The capacitor structure C_ST may be disposed on the landing pad LP. The capacitor structure C_ST may be connected to the landing pad LP. For example, the channel layer 450 and the capacitor structure C_ST may be electrically connected to each other through the landing pad LP.

The capacitor structure C_ST may include the lower electrode 130, the dielectric film 160, the conductive film 170, and the upper electrode 180. The first support 150 may be disposed on the upper surface of the lower electrode 130 and on a portion of the side surface extending from the upper surface of the lower electrode 130. The second support 152 may surround the middle portion of the lower electrode 130. Descriptions of the capacitor structure C_ST, the first support 150, and the second support 152 may be the same as those described in FIGS. 1 to 11.

Although not shown, the mask pattern MS may be disposed between the lower electrode 130 and the first support 150. The description of the mask pattern MS may be the same as that described above with reference to FIGS. 9 to 11.

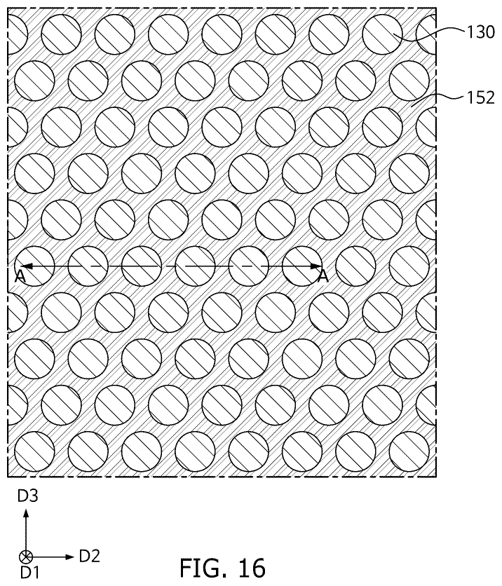

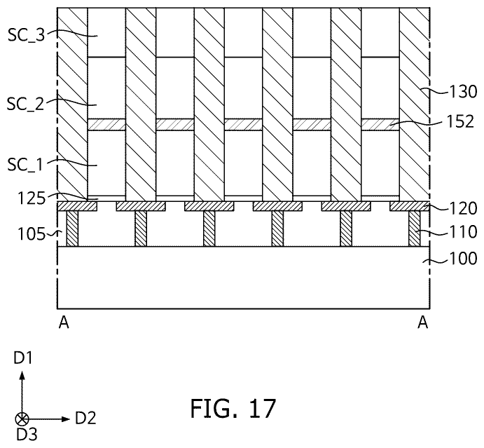

FIGS. 16 to 23 are diagrams illustrating a method for manufacturing a semiconductor device according to example embodiments. For reference, FIG. 16 is a plan view showing the intermediate stage in the manufacturing of the semiconductor device. FIGS. 17 to 23 are cross-sectional views taken along the line A-A of FIG. 16 example embodiments. For convenience of description, configurations other than the second support 152 and the lower electrode 130 are omitted from FIG. 16.

Referring to FIGS. 16 and 17, the contact plug 110, the landing pad 120, and the interlayer insulating film 105 may be formed on the substrate 100. The contact plug 110, the landing pad 120, and the interlayer insulating film 105 of FIG. 17 may correspond to the contact plug 110, the landing pad 120, and the interlayer insulating film 105 of FIG. 2. The etching stop film 125, a first sacrificial film SC_1, the second support 152, a second sacrificial film SC_2, and a third sacrificial film SC_3 may be sequentially stacked on the interlayer insulating film 105 and the landing pad 120.

The first sacrificial film SC_1, the second sacrificial film SC_2, and the third sacrificial film SC_3 may include the same or similar material. Each of the first sacrificial film SC_1, the second sacrificial film SC_2, and the third sacrificial film SC_3 may include silicon oxide or metal oxide. In example embodiments, the first sacrificial film SC_1 and the second sacrificial film SC_2 may include silicon oxide or metal oxide, and the third sacrificial film SC_3 may include metal nitride or silicon nitride. However, the inventive aspects are not limited to the above.

FIG. 17 illustrates an aspect in which three sacrificial film layers are employed, but the inventive aspects are not limited thereto. For example, two or four or more sacrificial film layers may be included.

The lower electrode 130 may be formed through the third sacrificial film SC_3, the second sacrificial film SC_2, the second support 152, the first sacrificial film SC_1, and the etching stop film 125. The lower electrode 130 may be formed by a process such as Chemical Vapor Deposition (CVD), Atomic Layer Deposition (ALD), or Plasma Enhanced ALD (PEALD).

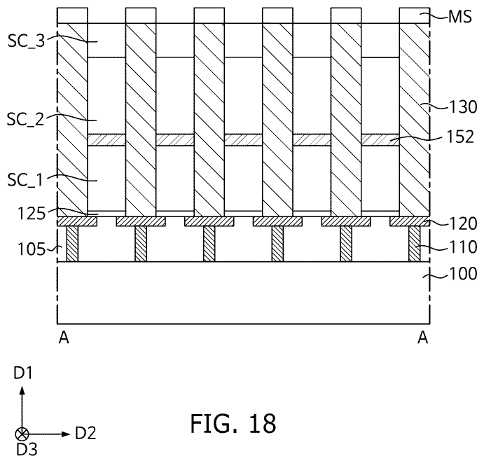

Referring to FIG. 18, a mask pattern MS may be formed on the lower electrode 130. The mask pattern MS may not be formed on the third sacrificial film SC_3. The mask pattern MS may be formed by Area Selective Deposition (ASD) process. The ASD process may include inducing material deposition on the upper surface of the lower electrode 130 by pre-defining a surface with different chemical activities.

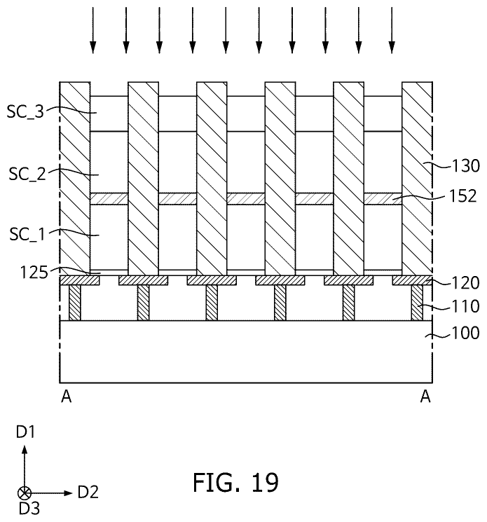

Referring to FIG. 19, a portion of the third sacrificial film SC_3 exposed by the mask pattern MS may be removed by the etching process, and an upper region of the lower electrode 130 may be exposed. For example, the etching process may be a dry etching process. The lower electrode 130 may have an etch selectivity with respect to the third sacrificial film SC_3. At least a portion of the mask pattern MS may remain in the process of removing the third sacrificial film SC_3.

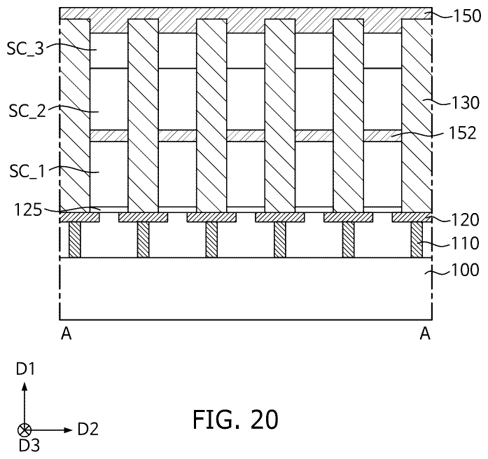

Referring to FIG. 20, the first support 150 may be formed on the upper region of the lower electrode 130 and on an upper surface of the remaining third sacrificial film SC_3. The upper surface of the first support 150 may be formed parallel to or substantially parallel to the upper surface of the substrate 100. However, the inventive aspects are not limited to the above. The first support 150 may extend along the shape of the lower electrode 130 exposed to the outside and along a profile of an upper surface of the third sacrificial film SC_3. The first support 150 may include a high vertical level portion and a low vertical level portion. The first support 150 may include a relatively high vertical level portion in a region overlapping with the lower electrode 130 in the first direction D1, and a relatively low vertical level portion in a region overlapping with the third sacrificial film SC_3 in the first direction D1.

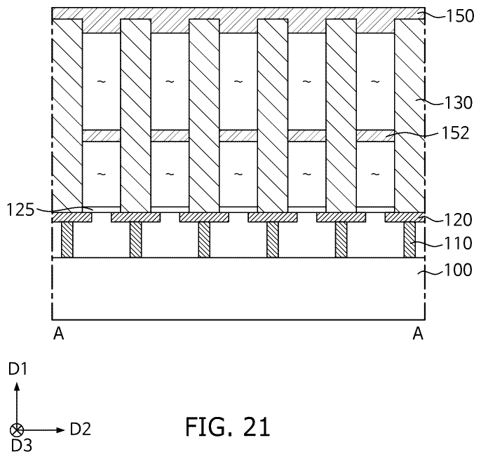

Referring to FIG. 21, the first sacrificial film SC_1, the second sacrificial film SC_2, and the third sacrificial film SC_3 may be removed by the etching process. The first sacrificial film SC_1, the second sacrificial film SC_2, and the third sacrificial film SC_3 may be removed by, for example, a wet etching process. However, the inventive aspects are not limited to the above.

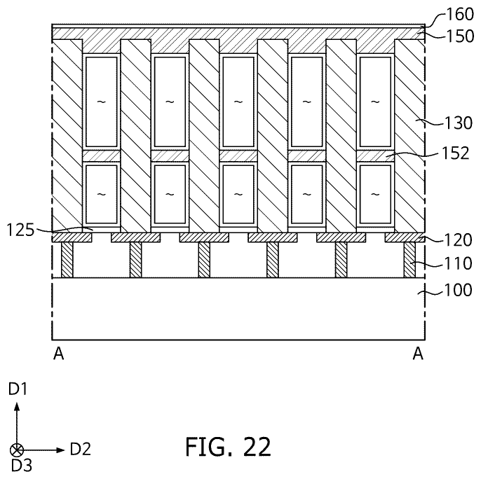

Referring to FIG. 22, the dielectric film 160 may be formed on the lower electrode 130, the first support 150, and the second support 152. The dielectric film 160 may be formed along a side surface of the lower electrode 130 exposed between the first support 150 and the second support 152, the lower surface of the first support 150, and the upper surface of the second support 152. In addition, the dielectric film 160 may be formed along the side surface of the lower electrode 130 exposed between the second support 152 and the etching stop film 125, the lower surface of the second support 152, and the upper surface of the etching stop film 125. In addition, the dielectric film 160 may be formed along the profile of the upper surface of the first support 150. The upper surface of the dielectric film 160 may be formed parallel to or substantially parallel to the upper surface of the substrate 100. However, the inventive aspects are not limited to the above. The dielectric film 160 formed on the first support 150 may include a high vertical level portion and a low vertical level portion. The dielectric film 160 may include a relatively high vertical level portion in a region overlapping with the lower electrode 130 in the first direction D1, and a relatively low vertical level portion in a region not overlapping with the lower electrode 130 in the first direction D1.

For example, the dielectric film 160 may be formed with a method such as Chemical Vapor Deposition (CVD), Atomic Layer Deposition (ALD), or PEALD.

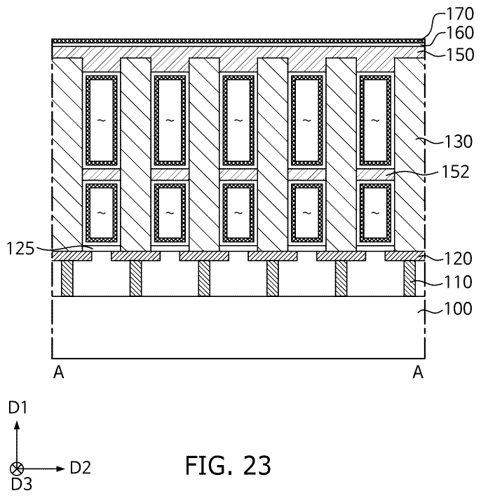

Referring to FIG. 23, the conductive film 170 may be formed on the dielectric film 160. The conductive film 170 may be formed along the profile of the dielectric film 160. For example, the conductive film 170 may be formed along the profile of the dielectric film 160 disposed on the lower electrode 130, the first support 150, the second support 152, and the etching stop film 125. The upper surface of the conductive film 170 may be formed parallel to or substantially parallel to the upper surface of the substrate 100. However, the inventive aspects are not limited to the above. The conductive film 170 formed on the dielectric film 160 may include a high vertical level portion and a low vertical level portion. The conductive film 170 may include a relatively high vertical level portion in a region overlapping with the lower electrode 130 in the first direction D1, and a relatively low vertical level portion in a region not overlapping with the lower electrode 130 in the first direction D1.

The conductive film 170 may be formed with a method such as Chemical Vapor Deposition (CVD), Atomic Layer Deposition (ALD), or PEALD.

Referring to FIG. 2, the upper electrode 180 may be formed on the conductive film 170 to form the capacitor structure C_ST, whereby the semiconductor device described with reference to FIGS. 1 to 8 may be provided. In addition, if the mask pattern MS remains on the lower electrode 130, the semiconductor device described with reference to FIGS. 9 to 11 may be provided.

While the inventive concept has been particularly shown and described with reference to embodiments thereof, it will be understood that various changes in form and details may be made therein without departing from the spirit and scope of the present invention as set forth in the following claims.

What is claimed is:

1. A semiconductor device, comprising:
a substrate;
a plurality of lower electrodes spaced apart from each other on the substrate in a second direction; and
a first support disposed on upper surfaces of the plurality of lower electrodes and on portions of side surfaces extending from the upper surfaces, wherein
the first support includes a first support portion overlapping with the plurality of lower electrodes in a first direction perpendicular to the second direction, and a second support portion between the plurality of lower electrodes,
each of the plurality of lower electrodes includes a protrusion positioned above a lower surface of the second support portion and a buried portion positioned below the lower surface of the second support portion, and
an upper surface of the protrusion is a flat surface and extends in the second direction.

2. The semiconductor device according to claim 1, wherein a side surface of the protrusion and a side surface of the buried portion are aligned in the first direction.

3. The semiconductor device according to claim 1, wherein a width of the upper surface of the protrusion is narrower than a width of a lower surface of the protrusion.

4. The semiconductor device according to claim 1, wherein a side surface of the protrusion has a concave shape.

5. The semiconductor device according to claim 1, wherein the second support portion includes a void therein.

6. The semiconductor device according to claim 1, wherein a width of the protrusion is narrower than a width of the buried portion in the second direction.

7. The semiconductor device according to claim 1, further comprising a mask pattern disposed between the first support and the upper surface of the protrusion in the first direction.

8. The semiconductor device according to claim 7, wherein a width of a lower surface of the mask pattern and a width of the upper surface of the protrusion correspond to each other.

9. The semiconductor device according to claim 7, wherein a side surface of the mask pattern is aligned with a side surface of the protrusion in the first direction.

10. The semiconductor device according to claim 7, wherein the mask pattern has a curved shape.

11. The semiconductor device according to claim 7, wherein a side surface of the mask pattern has a convex shape.

12. The semiconductor device according to claim 7, wherein the mask pattern gradually decreases in width in the second direction toward an upper portion thereof.

13. The semiconductor device according to claim 1, wherein a vertical level of the uppermost part on an upper surface of the first support portion is higher than a vertical level of the lowermost part on an upper surface of the second support portion.

14. The semiconductor device according to claim 1, further comprising:
a plurality of landing pads disposed between the substrate and the plurality of lower electrodes in the first direction and each connected to a corresponding one of the plurality of lower electrodes;
an upper electrode disposed on the plurality of lower electrodes; and
a dielectric film disposed between the plurality of lower electrodes and the upper electrode in the first direction.

15. The semiconductor device according to claim 1, further comprising a second support disposed on side surfaces of the plurality of lower electrodes.

16. A semiconductor device, comprising:
a substrate;
a plurality of lower electrodes spaced apart from each other on the substrate in a second direction, each extending in a first direction perpendicular to the second direction;
a support disposed on upper surfaces of the plurality of lower electrodes and on portions of side surfaces extending from the upper surfaces; and
a mask pattern disposed between at least one lower electrode of the plurality of lower electrodes and the support in the first direction.

17. The semiconductor device according to claim 16, wherein the mask pattern is disposed between a lower surface of a portion of the support and an upper surface of the at least one lower electrode.

18. The semiconductor device according to claim 16, wherein a side surface of the mask pattern is aligned with a side surface of the at least one lower electrode in the first direction.

19. The semiconductor device according to claim 16, wherein a side surface of the mask pattern has a convex shape in the second direction.

20. A semiconductor memory device, comprising:
a substrate including a plurality of transistors;
a capacitor structure disposed on the substrate and connected to the plurality of transistors, the capacitor structure including:
a plurality of lower electrodes each connected to a corresponding transistor, an upper electrode disposed on the plurality of lower electrodes, and a dielectric film disposed between the plurality of lower electrodes and the upper electrode; and
a support disposed on upper surfaces of the plurality of lower electrodes and on portions of side surfaces extending from the upper surfaces, wherein:
the support includes a first support portion overlapping with the plurality of lower electrodes in a first direction, and a second support portion between the plurality of lower electrodes,
each of the plurality of lower electrodes includes a protrusion positioned above a lower surface of the second support portion and a buried portion positioned below the lower surface of the second support portion, and
an upper surface of the protrusion is a flat surface and extends in a second direction perpendicular to the first direction.
